(19) United States
(12) Patent Application Publication
(10) Pub. No.: US 2005/0247923 A1
(43) Pub. Date: Nov. 10, 2005

(54) Semiconductor nano-structure and method of forming the same

(75) Inventors: Sae Chae Jeoung, Daejeon Metropolitan-city (KR); Myung Il Park, Seoul (KR); Jae Hyuk Choi, Daejeon Metropolitan-city (KR)

Correspondence Address: ST. ONGE STEWARD JOHNSTON & REENS, LLC, 986 BEDFORD STREET, STAMFORD, CT, 06905-5619, US

(73) Assignee: Korea Research Institute of Standards and Science

(21) Appl. No.: 11/119,149

(22) Filed: Apr. 29, 2005

(30) Foreign Application Priority Data
Apr. 29, 2004 (KR) 2004-30173

(51) Int. Cl. H01L 29/06

(52) U.S. Cl. 257/9

(57) ABSTRACT

A semiconductor nano structure having a germanium structure and a germanium nano structure formed on a surface of germanium structure is provided. In addition, a method of forming the semiconductor nano structure on a semiconductor structure by illumination of a pulse laser is provided. The pulse laser has pulse illumination period ranging from 10 pico-seconds to 1 femto-second. In addition, a laser fluence generated by the pulse laser is equal to or more than 14 J/cm². In addition, the germanium nano structure has a shape of sphere or a sphere-like shape such as a hemisphere with a radius of from 1 to 100 nanometers.

### BACKGROUND OF THE INVENTION

This application claims the priority of Korean Patent Application No. 2004-0030173, filed on Apr. 29, 2004, in the Korean Intellectual Property Office, the disclosure of which is incorporated herein in its entirety by reference.

### FIELD OF THE INVENTION

The present invention relates to a semiconductor structure and a method forming the same, and more particularly, to a semiconductor nanometer structure and a method of forming the same.

### RELATED ART

In general, it is known that a bulk of a monolith silicon (Si) or germanium (Ge) structure (hereinafter, a bulk structure) used for a semiconductor material does not have opto-electric, electro-optic, and electro-emissive properties.

However, it is also known that, as the Si or Ge structure is miniaturized down to the nanometer (herein below nano means nanometer) scale, the so-called quantum confinement effect is dominated. Due to the quantum confinement effect, the energy band gap of the Si or Ge structure can be widened. As a result, its electro-optical characteristics change, so that the Si or Ge structure in the nano scale (hereinafter, referred to as a nano structure) has an emissive property in a visible wavelength range. Typically, the nano structure is formed as particles separated from the bulk structure or as protrusions protruding from the surface often bulk structure in order to increase a ratio of surface area to volume.

Due to its emissive properties, the nano structure is used for a display device, an optical device, an optical sensor, and the like. Recently, various methods of forming Si or Si—Ge oxide nano structure have widely researched and developed. For example, there are a gas evaporation method (H. Morisaki, F. W. Ping, H. Ono and K. Yazawa, “Above-band-gap photoluminescence from Si fine particles with oxide shell” J. Appl. Phys. 70, 1991, p.1869); an RF magnetron co-sputtering method (Y. Maeda, N. Tsukamoto, Y. Yazawa, Y. Kanemitsu, and Y. Matsumoto, “Visible photoluminescence of Ge microcrystals embedded in SiO²” Appl. Phys. Lett. 59, 1991, p.3168).

The conventional methods of forming the nano structure include a chemical vapor deposition (CVD) method, a physical deposition (PD) method such as co-sputtering, and a electrochemical or chemical solution method. In the CVD and PD methods, a fine particle structure film is formed on a substrate. In the electrochemical or chemical solution method, electrochemical or chemical dissolution is used to form the fine particle structures on the substrate. In the CVD and PD methods, vacuum equipment is needed to form a low or high vacuum ambience. In addition, there is a need for a mechanism for accurately regulating source gas flow and a high-cleanness process facility. Since the vacuum equipment, the accurate source gas flow regulating mechanism, and the high-cleanness process facility are expensive, the CVD and PD methods are very expensive.

On the other hand, in the electrochemical or chemical solution method, it is difficult to prepare a fine solution and to control the crystallization condition for forming the nano structure on a substrate.

In addition, in the conventional methods, it is narrowly possible or difficult to form layers of the nano structures. Even though the layered nano structure can be formed, it is too rough to have only a resolution above tens of micrometers, and its electro-optical properties are not constant.

With respect to the Ge nano structure, any method of growing a pure Ge nano structure is not disclosed in the related art. In addition, in case of the aforementioned Si—Ge oxide nano structure, the Ge nano structure must be deposited on the Si oxide in a high vacuum, so that its usage and development have been limited. On the other hand, with respect to the Si nano structure, a method of forming Si nano structures having nano porous silicon has been developed. The Si nano structure emitting visible light has been developed and used for a variety of electronic devices and bio-devices. However, the Ge nano structure has not been widely developed and used for these devices. This is because the pure Ge nano structure is not obtained. According to a research, the optical properties of the Ge nano structure may be originated from not its pure structure but impurities or defect sites in an interface between the Ge nano structure and other materials. Therefore, the practical uses of the Ge nano structure have been limited.

### SUMMARY OF THE INVENTION

In order to solve the conventional problems, the present invention provides a method of forming a semiconductor nano structure.

The present invention also provides a method of forming a semiconductor nano structure by forming a germanium nano structure in a predetermined pure germanium structure.

The present invention also provides a method of forming a semiconductor nano structure in a room pressure instead of a specific vacuum ambience.

The present invention also provides a method of forming a semiconductor nano structure capable of controlling a nano structure formation region with a high resolution of submicron.

According to an aspect of the present invention, there is provided a semiconductor nano structure formed on a semiconductor substrate by illumination of a pulse laser.

In the aspect of the present invention, the semiconductor substrate may a monolithic substrate.

In addition, the semiconductor substrate may be a monolithic germanium substrate.

In addition, the pulse laser may be an ultra-fast pulsed laser. In addition, the ultra-fast pulsed laser may have a pulse illumination period ranging from 10 pico-seconds to 1 femto-second.

In addition, the illumination of the pulse laser may be performed with a laser illumination system using a galvano scanner to accurately illuminate a predetermined region of the substrate or to form a pattern at a high resolution.

In addition, the pulse laser may be selected according to semiconductor type, substrate thickness, or the like. In addition, for a typical thick substrate, a laser fluence generated by the pulse laser may be more than 10 J/cm², preferably, more than 14 J/cm². The nano structure is preferably formed in a shallow portion from the surface of the semiconductor substrate. However, since the nano structure can be formed in a deep portion from the surface of the semiconductor substrate, the upper value of the laser fluence is not limited.

According to another aspect of the present invention, there is provided a semiconductor nano structure comprising: a germanium structure; and a germanium nano structure formed on a surface of the germanium structure.

In the aspect of the present invention, the germanium structure may be formed in a monolithic germanium substrate; the germanium structure may have porous frame structures between ablative craters; and the porous frame structures may have a diameter of from 0.5 to 10 micrometers.

In addition, the germanium nano structure may have a shape of sphere with a radius of from 1 to 100 nanometers.

### BRIEF DESCRIPTION OF THE DRAWINGS

The above and other features and advantages of the present invention will become more apparent by describing in detail exemplary embodiments thereof with reference to the attached drawings in which:

FIG. 1 schematically shows an ultra-fast laser system used for a method of forming a nano structure according to the present invention;

FIG. 2 is an ×10000 SEM photograph of a specific region of a germanium substrate processed by illumination of the ultra-fast pulse layer;

FIG. 3 is an ×50000 SEM photograph of the specific region of the germanium substrate processed by illumination of the ultra-fast pulse laser;

FIG. 4 is a graph of an emission spectrum of the Ge nano structure of FIG. 3 by illumination of a He—Cd continuous laser at the room temperature and under ambient conditions; and

FIG. 5 is a graph of a Raman shift of the Ge nano structure of FIG. 3 by illumination of an Ar-ion continuous laser at the room temperature and ambient conditions.

### DETAILED DESCRIPTION OF THE PREFERRED EMBODIMENTS

Now, a nano structure and a method of forming the nano structure according to embodiments of the present invention will be described in detail with reference to the accompanying drawings.

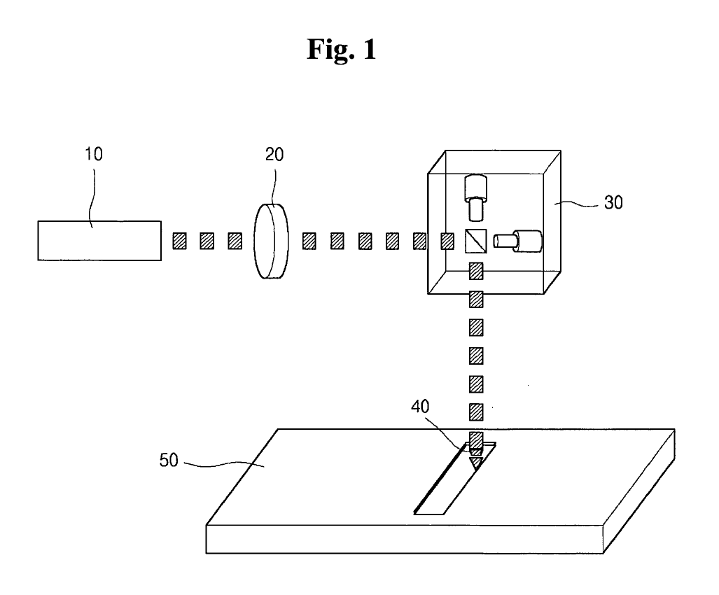

FIG. 1 schematically shows an ultra-fast laser system used for the method of forming a nano structure according to the present invention.

The ultra-fast laser system includes a laser pulse generator 10, a neutral density filter 20, and a galvano scanner 30. The laser pulse generator 10 has a femto-second (fs: 10⁻¹⁵ sec) laser. The laser has a repetition rate (period) of 1 kHz, a power of 1 mJ/pulse, an IR wavelength of 800 nm, and a pulse width of 150 fs. A laser pulse generated by the laser pulse generator 10 is input to the neutral density filter 20, an optical system for adjusting intensity of laser pulse. The neutral density filter 20 outputs a power (energy density) ranging from 0.7 to 50 J/cm². The power-adjusted laser pulse output from the neutral density filter 20 is transmitted to the galvano scanner 30. The galvano scanner 30 illuminates the laser pulse 40 on a test piece 50, which is a monolithic Ge substrate 50. The monolithic Ge substrate 50 is mounted on a z-moving stage (not shown). Due to the illumination of the laser pulse, line patterns are formed on a surface of the test piece.

More specifically, the laser pulse is a laser beam. Here, it is assumed that the laser beam has a spot size of 30 μm. However, since the spot size of 30 μm is not suitable for forming a line pattern having a width of 1 μm, an object lens is disposed in a predetermined position along the laser beam path. The object lens focuses the laser beam on the test piece with a test-position controlling unit.

In order to maximize the ratio of surface area to volume of the Ge nano structure in the predetermined region of the Ge structure, there is needed a specific process condition for ultra-fast laser system. In order to obtain the process condition, optical measurement is performed on the laser-pulse-illuminated surface of the Ge nano structure while changing the laser fluence. In addition, there are various factors for adjusting the ultra-fast laser system. For example, these factors include a laser pulse period, a laser pulse power, a laser beam size, a laser beam focusing rate, and a scan speed of the galvano scanner. These factors must be collectively taken into consideration. The collective factor is the laser fluence, which is defined as a total energy illuminated per a unit area of the processed substrate.

When a series of pulsed laser beams are illuminated, the precedent laser pulse must not influence the latter laser pulse. Therefore, the galvano scanner 30 adjusts the laser beam scan speed. For example, the laser beam scan speed is fixed at 200 mm/sec. By the laser pulse, a large amount of energy is instantaneously focused on a localized region of the substrate. As a result, the state of material in the localized region is transitioned. In particular, in the localized region, explosive ablation occurs to generate craters. The craters are consecutively formed on the substrate. In addition, a porous frame structure, that is, a three-dimensional network structure is formed under specific conditions of the laser pulse period, the scan speed, and the energy per pulse. The porous frame structures have a diameter of from 0.5 to 10 micrometers.

The diameter of the crater is represented by the following Equation 1. Here, D is the diameter of the crater, F₀ is a maximum laser fluence, Fₜₕ is a processing threshold fluence which is a laser fluence at a distance r=D/2 from a center of a spot, and w is an effective laser illumination radius which is a distance where a power of laser beam is 1/e² of the maximum power at a center of a spot.
D²=2W²In(F₀/Fₜₕ) [Equation 1]
Equation 1 can be derived from the following Equation 2.
F(r)=F₀ exp(−2r²/w²) [Equation 2]

Equation 2 shows the one-dimensional distribution of the laser fluence of a laser beams under the assumption that the laser fluence has a Gaussian distribution.

As seen in Equation, the processing threshold fluence Fₜₕ and the effective laser illumination radius w can be obtained in a semi-logarithm plot of a laser fluence F(r) and a square of the diameter of ablation region (that is, the diameter of crater). In addition, as seen in Equation, the semi-logarithm plot is divided into two different fluence regions. The two different fluence regions are experimentally obtained. Namely, it can be understood that there are different correlation patterns between the laser pulse and the Ge structure in the two different fluence regions.

More specifically, in a lower fluence region (8 J/cm² or less), the measured processing threshold fluence Fₜₕ and effective laser illumination radius are 0.58 J/cm² and 18.3 μm, respectively. In a higher fluence region (14 J/cm² or more), the measured processing threshold fluence Fₜₕ and effective laser illumination radius are 6.2 J/cm² and 39.6 μm, respectively. In the present invention, the higher fluence region is utilized.

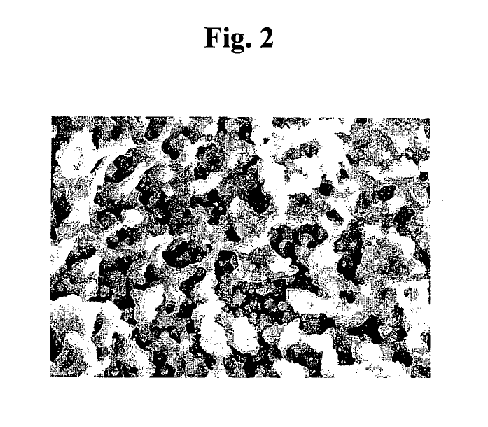

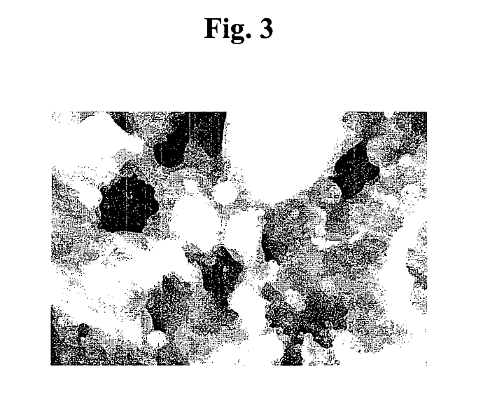

FIG. 2 is an ×10000 SEM (scanning electron microscopy) photograph of a specific region of a germanium substrate (wafer) processed by illumination of the ultra-fast pulse layer. FIG. 3 is an ×50000 SEM photograph of the specific region.

As shown in the SEM photographs, the Ge substrate undergoes ablation, so that 3-dimensional Ge micro structures are non-uniformly distributed between craters to form a porous frame structure. Here, the fluence of the ultra-fast pulse laser is 45.3 J/cm². In the photographs, since the size of the processed region is 11.5×8 μm², the size of the Ge micro structure is about 1 μm. The Ge micro structure is so far smaller than the beam spot of the ultra-fast laser pulse laser.

In addition to the Ge micro structures, Ge nano structures can be seen in the photographs. The Ge nano structures substantially have a shape of a sphere. The radius of the sphere ranges from several to 100 nanometers. Due to the Ge nano structures, it is possible to greatly increase the ratio of surface area to volume.

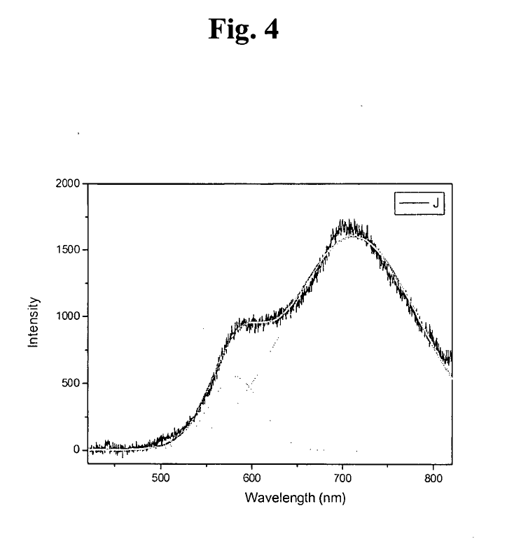

FIG. 4 is a graph of an emission spectrum of the Ge nano structure of FIG. 3 by illumination of a He—Cd continuous laser at the room temperature and under ambient conditions. FIG. 4 shows characteristics and applicability of the Ge nano structure.

In visible wavelength region, orange-red emission a relatively large intensity is observed. Therefore, the Ge nano structure can be perceived with human eyes. In its normal state, the Ge having an energy band gap (between valence and conduction bands) of 0.67 eV is an indirect semiconductor. Namely, the Ge cannot emit visible light in its normal state. However, like the Si nano structure, the Ge (that is, Ge nano structure) processed according to the present invention can emit visible light. Therefore, it can be understood that the Ge nano structure is originated from the so-called “quantum confinement.”

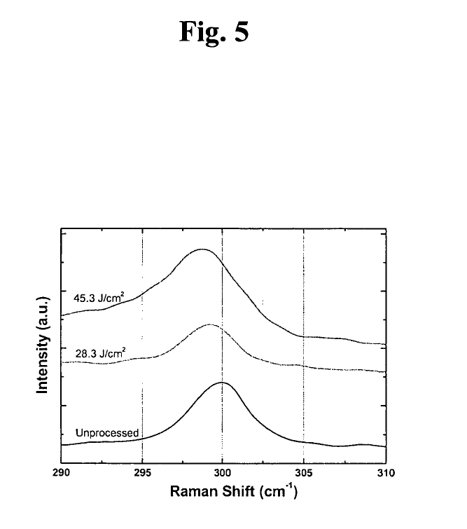

FIG. 5 is a graph of a Raman shift of the Ge nano structure of FIG. 3 by illumination of an Ar-ion continuous laser at the room temperature. After the illumination process, the phonon vibration mode of the Ge lattice is shifted into a Raman vibration mode (1.5 cm⁻¹). This is called a Raman shift. The Raman shift shows that the Ge nano structure is originated from the quantum confinement.

By using the aforementioned visible emission, the Ge nano structure can be used for a sensor for sensing a trajectory of a non-visible laser. In addition, the Ge nano structure can be used as a fluorescent element for a display device since the Ge nano structure emits visible light according to sizes of the quantum dots and hot electros under an electric field. In particular, the Ge nano structure can be used for a display panel since a fine pattern of the Ge nano structure can be formed by using a laser scanning apparatus.

According to the present invention, it is possible to obtain a pure semiconductor nano structure. In particular, it is possible to form a Ge nano structure in a predetermined region of a pure Ge structure.

In addition, according to the present invention, since a semiconductor nano structure can be formed in a room pressure instead of a specific vacuum ambience, highly expensive vacuum equipment is unnecessary, so that it is possible to reduce production cost of the semiconductor nano structure.

In addition, according to the present invention, since an ultra-fast pulse laser is used as a laser source for a laser beam scanning apparatus such as a galvano scanner, it is possible to accurately control a pattern size of the Ge nano structure at a high resolution of micrometer or less.

While the present invention has been particularly shown and described with reference to exemplary embodiments thereof, it will be understood by those skilled in the art that various changes in form and details may be made therein without departing from the spirit and scope of the present invention as defined by the appended claims.

1. A semiconductor nano structure formed on a semiconductor substrate by illumination of a pulse laser.

2. The semiconductor nano structure according to claim 1, wherein the pulse laser has a pulse illumination period ranging from 10 pico-seconds to 1 femto-second.

3. The semiconductor nano structure according to claim 1, wherein the illumination of the pulse laser is performed with a laser illumination system using a galvano scanner.

4. The semiconductor nano structure according to claim 1, wherein a laser fluence generated by the pulse laser is equal to or more than 14 J/cm².

5. The semiconductor nano structure according to claim 1, wherein the semiconductor substrate is a monolithic germanium substrate.

6. A semiconductor nano structure comprising:
a germanium structure; and
a germanium nano structure formed on a surface of the germanium structure.

7. The semiconductor nano structure according to claim 6,
wherein the germanium structure is formed in a monolithic germanium substrate,
wherein the germanium structure has porous frame structures between ablative craters, and
wherein the porous frame structures have a diameter of from 0.5 to 10 micrometers.

8. The semiconductor nano structure according to claim 6, wherein the germanium nano structure has a shape of sphere with a radius of from 1 to 100 nanometers.
